(19) United States
(12) Patent Application Publication
(10) Pub. No.: US 2012/0235304 A1
(43) Pub. Date: Sep. 20, 2012

(54) ULTRAVIOLET (UV)-REFLECTING FILM FOR BEOL PROCESSING

(75) Inventors: Torsten Huisinga, Dresden (DE); Ralf Richter, Dresden (DE); Ulrich Mayer, Dresden (DE)

(73) Assignee: GLOBALFOUNDRIES Inc., Grand Cayman (KY)

(21) Appl. No.: 13/051,461

(22) Filed: Mar. 18, 2011

(51) Int. Cl. H01L 23/48; H01L 21/28

(52) U.S. Cl. 257/773; 438/618; 438/675; 257/E21.158; 257/E23.01

(57) ABSTRACT

Semiconductor devices are formed with a dielectric stack by forming an UV reflecting layer between cured and uncured ULK layers during BEOL processing. Embodiments include forming a first ultra low-k (ULK) layer on a semiconductor element, curing the first ULK layer, forming an ultraviolet (UV) reflecting layer on the first ULK layer, forming a second ULK layer on the UV reflecting layer, and irradiating the second ULK layer with UV light.

### TECHNICAL FIELD

The present disclosure relates to a method and apparatus for preventing delamination of a semiconductor chip due to ultraviolet radiation associated with the semiconductor processing. The present disclosure is particularly applicable to preventing cured ultra low-κ dielectric (“ULK”) materials from being re-exposed to ultraviolet light.

### BACKGROUND

In the manufacture of semiconductors, ultraviolet (UV) radiation is applied during various processes. For example, UV radiation plays a prominent role during metal interconnect back end of line (BEOL) processing for curing ultra low-κ interlayer dielectric (ILD) layers. BEOL processing includes interconnection of individual devices (transistors, capacitors, resistors, etc.) with wiring on the wafer, as well as formation of contacts, insulating layers (dielectrics), metal levels, and bonding sites for chip-to-package connections.

As shown in FIG. 1, a conventional semiconductor device includes an ultra low-κ dielectric (ULK) layer 101, a dielectric cap layer 103 such as nitrogen-doped silicon carbide (NBLOK), hereinafter referred to as NBLOK layer 103, interconnects 105, a ULK layer 107, and an NBLOK layer 109. There also may be multiple ULK cured layers (not shown for illustrative convenience) beneath NBLOK layer 109. In semiconductor manufacturing, a low-κ dielectric is considered a material with a dielectric constant less than 3.9 (the dielectric constant of silicon dioxide), an ultra low-κ dielectric refers to a dielectric constant much smaller than 3.9, and a high-κ dielectric is a material with a dielectric constant greater than 3.9. NBLOK layers 103 and 109 have a higher κ than the ULK layers 101 and 107.

The primary function of the NBLOK layers 103 and 109 is to prevent electromigration (EM) failure of interconnects 105, which becomes a serious reliability threat when the dimensions of the interconnects approach the nanoscale range. Since NBLOK layers 103 and 109 have intrinsically high κ values, their thicknesses must be minimized to reduce electromigration from the interconnects to the ULK layers.

ULK is a porous material which is mechanically weaker than dense ILDs (e.g., about 30% lower breakdown strength) and suffers from mechanical instability (i.e., relative low Young's modulus). Thus, ULK is more sensitive to process damage and prone to cracks or delamination during packaging, i.e. poor chip package interaction (CPI).

The integration of ULK layers is challenging, for example, due to an etch process for etching the trench for an interconnect 105, and liner processes for smoothing the etch edges, etc. The etch process introduces a damage region which increases the effective κ-value of the ULK 107. The liner processes smoothly etch back the edges to allow reliable ULK integration.

Both the ULK mechanical properties (hardness, modulus . . . ) and the adhesion strength between ULK layers or metallic layers are factors affecting package strength, since cracks can occur due to multi-stack global stress or wire-bonding. In particular, the ULK mechanical properties ensure the capability of the ULK material to support/survive all the processing steps including metal re-crystallization and packaging. The adhesion strength ensures stack stability during local or global stress variations including thermal treatments.

To improve the Young's modulus of ULK layer 107, a UV-curing process is applied immediately after deposition of ULK layer 107, in order to cross-link the ULK material and improve its mechanical stability. Young's modulus is defined as a ratio of longitudinal stress to longitudinal strain. Young's modulus is symbolized by E and is a measure of the stiffness of an isotropic elastic material.

After ULK layer 107 is UV-cured, ULK layer 101 is deposited, and another UV-curing process is applied. As shown in FIG. 1, UV 111 penetrates not only into the un-cured ULK layer 101, but also into NBLOK layer 103 and UV-cured ULK layer 107. Since NBLOK layers 103 and 109 are made thin to avoid EM failure, thickness variations occur between the ULK layers and the NBLOK layers. The thickness variations can trigger curing ULK layer 107 through the NBLOK layers (particularly NBLOK layer 103), which produces stress, thereby causing delamination of the semiconductor structure. The NBLOK material also must be chosen to avoid absorption of the UV radiation, as such absorption introduces mechanical stress to the already integrated ULK layers below.

A need therefore exists for methodology enabling integrated ULK layers (i.e., a stack) with high mechanical stability (e.g., Young's modulus), and the resulting semiconductor device.

### SUMMARY

An aspect of the present disclosure is a method of forming a dielectric stack in an integrated circuit by providing a UV reflecting layer over already cured ULK layers during BEOL processing.

Another aspect of the present disclosure is a device with a dielectric stack including a UV reflecting layer over already cured ULK layers.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a first ultra low-κ (ULK) layer on a semiconductor element; curing the first ULK layer; providing an ultraviolet (UV) reflecting layer on the first ULK layer; providing a second ULK layer on the UV reflecting layer; and irradiating the second ULK layer with UV light.

Aspects of the present disclosure include forming metal interconnects in the first ULK layer subsequent to curing the first ULK layer. Further aspects include providing an NBLOK layer over the metal interconnects; and subsequently forming the UV reflecting layer. Another aspect includes providing the NBLOK layer with a k-value of 5.3. Additional aspects include providing the NBLOK layer to a thickness of 200 Å to 1000 Å. Further aspects include providing the first and second ULK layers including a material having a dielectric constant of 2.2 to 2.55. Other aspects include providing the first and second ULK layers of porous organosilicate glass, porous fluorine-doped silicate glass, or a combination thereof. Another aspect includes providing the UV reflecting layer including a low k silicon oxide. Further aspects include providing the UV reflecting layer to a thickness of 3 nm to 10 nm. Additional aspects include providing the UV reflecting layer of silicon oxide doped with aluminum oxide.

Another aspect of the present disclosure is a device including: a first UV cured ultra low-k (ULK) layer over a semiconductor element; an ultraviolet (UV) reflecting layer over the first ULK layer; and a second ULK layer over the UV reflecting layer.

Aspects include devices including metal interconnects in the first ULK layer. Further aspects include devices including an NBLOK layer over the metal interconnects. Another aspect includes devices including an NBLOK layer having a k-value of 5.3 and a thickness of 200 Å to 1000 Å. Another aspect includes devices including first and second ULK layers having a dielectric constant of 2.2 to 2.55. Additional aspects include devices including first and second ULK layers including porous organosilicate glass, porous fluorine-doped silicate glass, or a combination thereof. Other aspects include devices including a UV reflecting layer including a low k silicon oxide. Further aspects include devices including a UV reflecting layer having a thickness of 3 nm to 10 nm. Another aspect includes devices including a UV reflecting layer including silicon oxide doped with aluminum oxide.

Another aspect of the present disclosure is a method including providing a first NBLOK layer over a semiconductor structure including at least one semiconductor element; providing a first ULK layer over the first NBLOK layer; irradiating UV light on the first ULK layer; etching trenches in the first ULK layer; filling the trenches with metal to form metal interconnects; providing a second NBLOK layer, over the metal interconnects, to a thickness of 200 Å to 1000 Å; providing a silicon oxide UV reflecting layer to a thickness of 3 nm to 10 nm over the second NBLOK layer; providing a second ULK layer over the second NBLOK layer; and irradiating UV light on the second ULK layer.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a conventional semiconductor device;

FIG. 2 schematically illustrates a semiconductor device in accordance with an exemplary embodiment; and

FIGS. 3A through 3F schematically illustrate a process flow for forming the semiconductor structure of FIG. 2, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of damage to cured ULK layers in a semiconductor device due to ultraviolet radiation associated with BEOL semiconductor fabrication processes. In accordance with embodiments of the present disclosure, a thin UV reflecting layer is formed on an NBLOK layer between UV-cured and uncured ultra low-κ dielectric layers to prevent UV radiation from reaching the previously cured ULK layer.

Methodology in accordance with embodiments of the present disclosure includes providing a first ULK layer on a semiconductor element; curing the first ULK layer; providing a UV reflecting layer on the first ULK layer; providing a second ULK layer on the UV reflecting layer; and irradiating the second ULK layer with UV light.

Still other aspects, features, and technical effects of preventing ultra low-κ dielectric materials from curing through a metal layer underneath will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

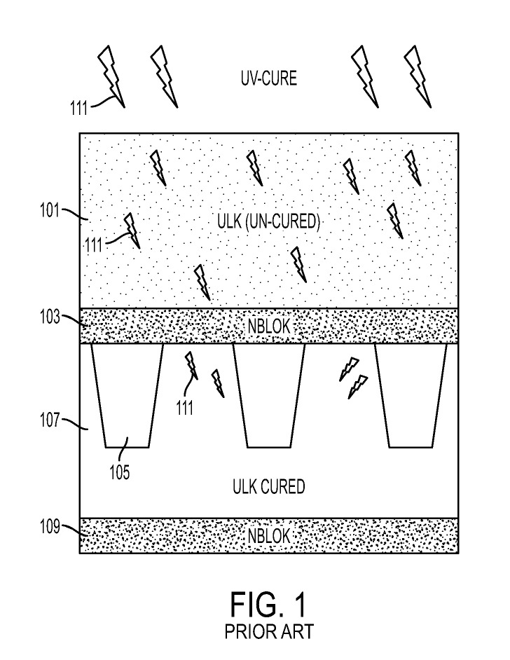

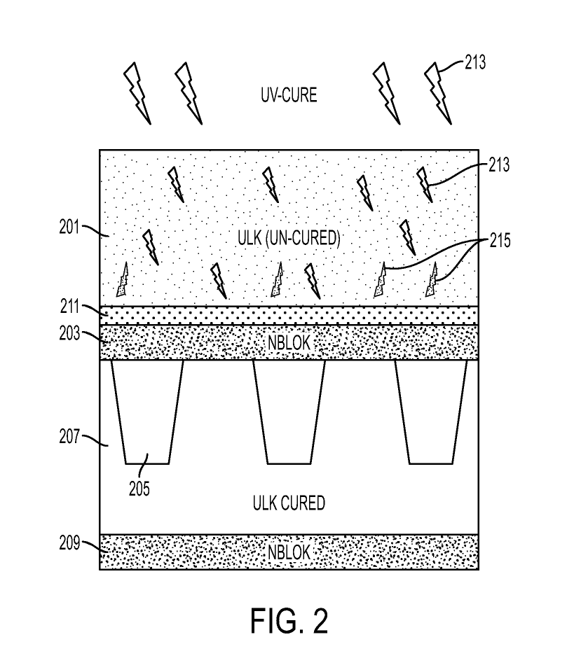

Adverting to FIG. 2, in accordance with an exemplary embodiment, a semiconductor device is formed with a UV reflecting layer between ULK layers. The semiconductor device of FIG. 2 includes a ULK layer 201, a NBLOK layer 203, interconnects 205, a ULK layer 207, and a NBLOK layer 209, similar to the layers in the device of FIG. 1. In addition, FIG. 2 includes a UV reflecting layer 211 to block the UV radiation 213 from penetrating through NBLOK layer 203, and reaching ULK layer 207.

ULK layers 201 and 207 may, for example, include a porous material including silicon (Si), carbon (C), oxygen (O), and hydrogen (H), or porous SiCOH or porous organosilicate glass (OSG). The ULK layers may alternatively include a fluorine-doped silicate glass (FSG). OSG films can deliver lower k (k=2.7), and are typically deposited by CVD using organosilane precursors or spin-on using silsesquioxanes. FSG may be deposited by CVD with the addition of SiF₄, and the k value of FSG is 3.6 (upper limit on atomic % F). The dielectric constant of the low-k material may then be reduced, for example to 2.2 to 2.55, by increasing the porosity of the film. ULK layers 201 and 207 may have a Young's modulus of 3 GPa to 8 GPa, and may initially be formed to a thickness of 1500 Å to 5000 Å. Other ILD layers (not shown for illustrative convenience) may also be formed, for example of SiCOH/TEOS, with k-values of 2.7 to 4.1 and a Young's modulus of 7 GPa to 20 GPa. The other ILD layers may be formed to a thickness of 1,500 Å to 30,000 Å.

NBLOK layers 203 and 209 may, for example, be formed of silicon carbon nitride (SiCNH), which has a k-value of 5.3 and a Young's modulus of 100 GPa. To compensate for the high k-value, NBLOK layers 203 and 209 may be formed to a thickness of 200 Å to 1000 Å.

The UV reflecting layer 211 may be formed of any ILD material that is capable of reflecting UV radiation. For example, UV reflecting layer 211 may be formed of silicon oxide (SiOₓ) with a k value less than the various ILD layers and may be formed to a thickness of 3 nm to 10 nm. Alternatively, UV reflecting layer 211 may be formed of an oxide doped with, for example, Al₂O₃. Reflecting layer 211 reflects the UV 213 back into the ULK layer 201 as reflected UV 215.

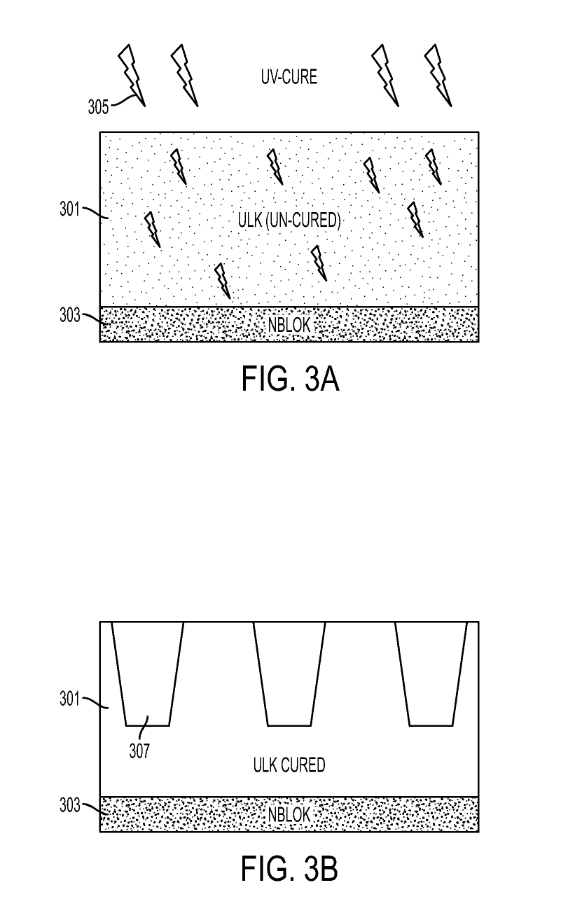

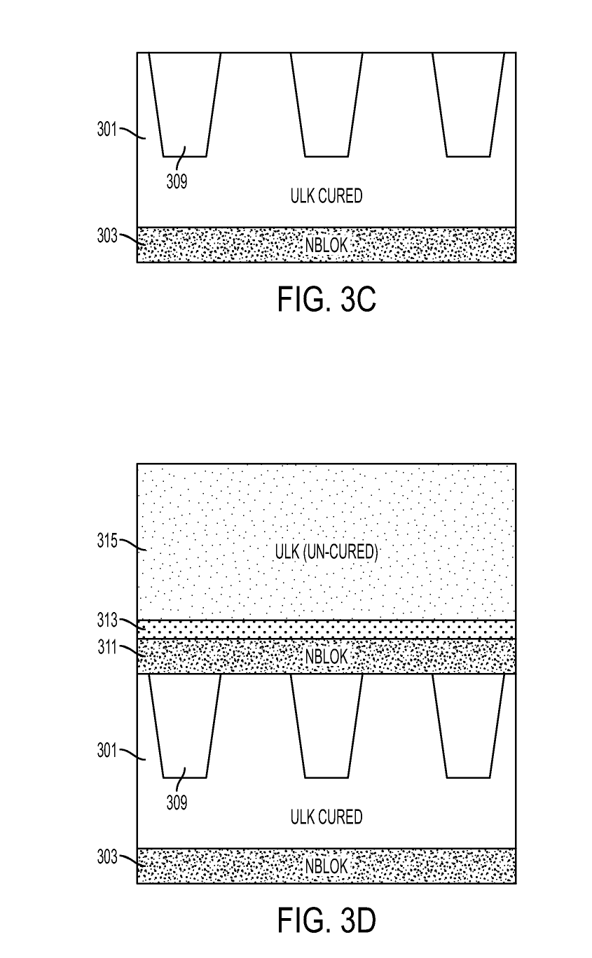

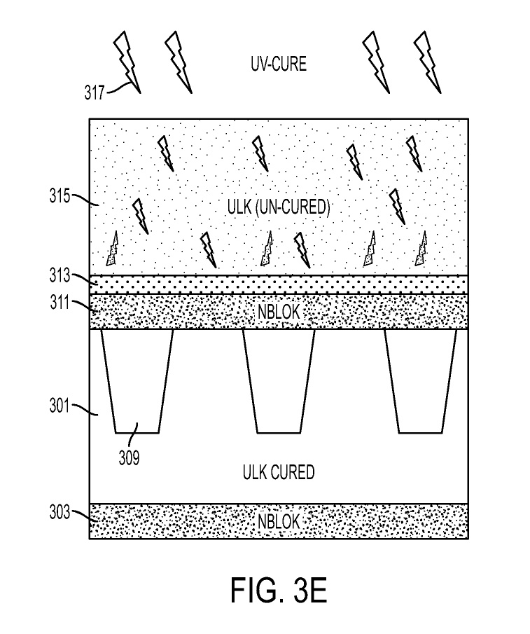

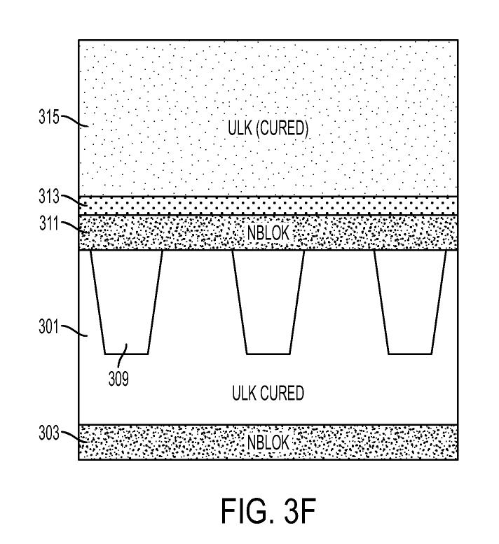

FIGS. 3A through 3F schematically illustrate a process flow for fabricating a semiconductor device such as that shown in FIG. 2. As illustrated in FIG. 3A, ULK material 301 is deposited on NBLOK layer 303, and then cured with UV radiation 305, for example for 50 seconds (sec) to 300 sec.

After ULK layer 301 is UV-cured, an etching process is applied to the UV-cured ULK layer 301 to create trenches 307, as illustrated in FIG. 3B. Etching may, for example, be chemical, plasma, physical (ion milling), or reactive ion etching.

A metal, such as copper or copper alloy, is deposited into trenches 307, for example by electrochemical plating, electroless plating, or chemical vapor deposition, to form metal interconnects 309, as illustrated in FIG. 3C. Although three metal interconnects are shown in FIG. 3C, the number of interconnects will depend on the particular application and is not limited to three. A metal barrier layer (not shown for illustrative convenience) may be formed on the bottom and sidewalls of the copper interconnects 309 prior to copper filling. The copper fill may also be accompanied by planarization, such as chemical mechanical polishing, to remove excess copper or copper alloy from the ULK layer.

As illustrated in FIG. 3D, NBLOK layer 311, UV reflecting layer 313, and ULK layer 315 are then sequentially deposited. The ULK layer 315 is then cured with UV radiation 317, for example for 50 sec to 300 sec, as illustrated in FIG. 3E. During the UV-curing processing, the UV reflecting layer 313 prevents the ULK layer 307 from curing again through NBLOK layer 311, while redirecting UV radiation 317 back into ULK layer 315, thereby improving the curing of the bottom portion of ULK layer 315. Curing of ULK layers 301 and 315 causes shrinkage in the thickness of the layers. For example, for a ULK layer with a k-value of 2.4, shrinkage may be 10% to 20%. For ULK layers with k-values of 2.55, shrinkage may be 5% to 12%. A semiconductor with a better-integrated ULK stack thus formed as illustrated in FIG. 3F.

The embodiments of the present disclosure can achieve several technical effects, including improved curing and, thus, more homogeneous Young's modulus, of upper level ULK layers, reduced stress in lower ULK layers, and overall improved CPI performance. The present disclosure enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a first ultra low-k (ULK) layer on a semiconductor element;
curing the first ULK layer;
providing an ultraviolet (UV) reflecting layer on the first ULK layer;
providing a second ULK layer on the UV reflecting layer; and
irradiating the second ULK layer with UV light.

2. The method according to claim 1, further comprising forming metal interconnects in the first ULK layer subsequent to curing the first ULK layer.

3. The method according to claim 2, further comprising:
providing an NBLOK layer over the metal interconnects; and
subsequently forming the UV reflecting layer.

4. The method according to claim 3, comprising providing the NBLOK layer with a k-value of 5.3.

5. The method according to claim 4, comprising providing the NBLOK layer to a thickness of 200 Å to 1000 Å.

6. The method according to claim 5, comprising providing the first and second ULK layers comprising a material having a dielectric constant of 2.2 to 2.55.

7. The method according to claim 6, comprising providing the first and second ULK layers of porous organosilicate glass, porous fluorine-doped silicate glass, or a combination thereof.

8. The method according to claim 6, comprising providing the UV reflecting layer comprising a low k silicon oxide.

9. The method according to claim 8, comprising providing the UV reflecting layer to a thickness of 3 nm to 10 nm.

10. The method according to claim 9, comprising providing the UV reflecting layer of silicon oxide doped with aluminum oxide.

11. A device comprising:
a first UV cured ultra low-k (ULK) layer over a semiconductor element;
an ultraviolet (UV) reflecting layer over the first ULK layer; and
a second ULK layer over the UV reflecting layer.

12. The device according to claim 11, further comprising metal interconnects in the first ULK layer.

13. The device according to claim 12, further comprising an NBLOK layer over the metal interconnects.

14. The device according to claim 13, wherein the NBLOK layer has a k-value of 5.3 and a thickness of 200 Å to 1000 Å.

15. The device according to claim 14, wherein the first and second ULK layers have a dielectric constant of 2.2 to 2.55.

16. The device according to claim 15, wherein the first and second ULK layers include porous organosilicate glass, porous fluorine-doped silicate glass, or a combination thereof.

17. The device according to claim 16, wherein UV reflecting layer comprises a low k silicon oxide.

18. The device according to claim 17, wherein the UV reflecting layer has a thickness of 3 nm to 10 nm.

19. The device according to claim 18, wherein the UV reflecting layer comprises silicon oxide doped with aluminum oxide.

20. A method comprising:
providing a first NBLOK layer over a semiconductor structure including at least one semiconductor element;
providing a first ULK layer over the first NBLOK layer;
irradiating UV light on the first ULK layer;
etching trenches in the first ULK layer;
filling the trenches with metal to form metal interconnects;
providing a second NBLOK layer, over the metal interconnects, to a thickness of 200 Å to 1000 Å;
providing a silicon oxide UV reflecting layer to a thickness of 3 nm to 10 nm over the second NBLOK layer;
providing a second ULK layer over the second NBLOK layer; and
irradiating UV light on the second ULK layer.
